(19) United States
(12) Patent Application Publication
(10) Pub. No.: US 2014/0353675 A1
(43) Pub. Date: Dec. 4, 2014

(54) ELECTRODE, MIS SEMICONDUCTOR DEVICE AND MANUFACTURING METHOD OF ELECTRODE

(71) Applicant: TOYODA GOSEI CO., LTD., Kiyosu-shi (JP)

(72) Inventors: Junya Nishii, Kiyosu-shi (JP); Toru Oka, Kiyosu-shi (JP)

(73) Assignee: TOYODA GOSEI CO., LTD., Kiyosu-shi (JP)

(21) Appl. No.: 14/281,724

(22) Filed: May 19, 2014

(30) Foreign Application Priority Data
May 29, 2013 (JP) 2013-112567

(51) Int. Cl. H01L 29/423; H01B 13/00; H01L 29/78; H01L 29/49; H01B 1/02; H01L 29/20

(52) U.S. Cl. CPC H01L 29/42376; H01B 1/023; H01L 29/2003; H01L 29/78; H01L 29/4966; H01B 13/0026; H01B 13/0016
USPC 257/76; 174/119 R; 427/123

(57) ABSTRACT

An electrode used in contact with an insulator comprises a layer mainly consisting of aluminum (Al) and a titanium nitride (TiN) layer that is placed between the layer mainly consisting of aluminum (Al) and the insulator and is arranged in contact with the layer mainly consisting of aluminum (Al). A ratio of thickness of the layer mainly consisting of aluminum (Al) to thickness of the titanium nitride (TiN) layer is in a range of not less than 3.00 and not greater than 12.00.

### CROSS REFERENCE TO RELATED APPLICATIONS

The present application claims the priority based on Japanese Patent Application No. 2013-112567 filed on May 29, 2013, the disclosure of which is hereby incorporated by reference in its entirety.

### BACKGROUND OF THE INVENTION

1. Technical Field

The present invention relates to an electrode used for, e.g., elements and circuit boards.

2. Description of Related Art

An electrode having a multi-layered structure including an aluminum (Al) layer and a titanium nitride (TiN) layer has been used as an electrode used for an element such as a transistor or a circuit board where elements are integrated. The titanium nitride layer is formed, for example, with a view to suppressing electromigration in the aluminum layer. In this electrode, arranging the aluminum layer and the titanium nitride layer in contact with each other may cause the occurrence of void (concave deformation) or hillock (convex deformation) on the surface of the electrode due to heating. One proposed technique provides a crystalline degradation layer having the intentionally degraded crystallinity of titanium nitride between the aluminum layer and the titanium nitride layer (JP 2006-313778A).

### SUMMARY OF INVENTION

The technique of providing the crystalline degradation layer between the aluminum layer and the titanium nitride layer needs a process of forming the crystalline degradation layer. This leads to problems of the complicated production process of the electrode and the increased production cost. These problems are not limited to the electrode of the two-layered structure including the aluminum layer and the titanium nitride layer but may also arise in an electrode of a three-layered structure having an aluminum layer provided between two titanium nitride layers. There is accordingly a demand for technology that suppresses the occurrence of void and hillock on the surface of an electrode having an aluminum layer and a titanium nitride layer due to heating, while reducing the production cost of the electrode. There are also demands for downsizing of the electrode and for saving power and saving resource during production.

In order to solve at least part of the problems described above, the invention may be implemented by the following aspects.

(1) According to one aspect of the invention, there is provided an electrode used in contact with an insulator. The electrode includes a layer mainly consisting of aluminum (Al); and a titanium nitride (TiN) layer that is placed between the layer mainly consisting of aluminum (Al) and the insulator and is arranged in contact with the layer mainly consisting of aluminum (Al), wherein a ratio of thickness of the layer mainly consisting of aluminum (Al) to thickness of the titanium nitride (TiN) layer is in a range of not less than 3.00 and not greater than 12.00. The electrode of this aspect suppresses the occurrence of void (concave deformation) and hillock (convex deformation) on the surface of the electrode due to heating. Additionally, this structure has no need to provide a crystalline degradation layer between the titanium nitride (TiN) layer and the layer mainly consisting of aluminum (Al) and thereby reduces the production cost of the electrode. Controlling the ratio of the thickness of the layer mainly consisting of aluminum (Al) to the thickness of the titanium nitride (TiN) layer to be not greater than 12.00 relatively increases the relative thickness of the titanium nitride (TiN) layer relative to the thickness of the layer mainly consisting of aluminum (Al). Titanium nitride has the higher melting point than that of aluminum. Relatively increasing the relative thickness of the titanium nitride (TiN) layer enables the titanium nitride (TiN) layer to be used for suppressing contraction of the layer mainly consisting of aluminum (Al) due to heating. This suppresses the occurrence of hillock on the surface of the electrode. Controlling the ratio of the thickness of the layer mainly consisting of aluminum (Al) to the thickness of the titanium nitride (TiN) layer to be not less than 3.00 suppresses the relative thickness of the titanium nitride (TiN) layer from being excessively increased relative to the thickness of the layer mainly consisting of aluminum (Al). This suppresses the occurrence of void caused by excessive suppression of the contraction of the layer mainly consisting of aluminum (Al) due to heating. The electrode of this aspect suppresses the occurrence of void and hillock even when the temperature of the heat treatment described above is equal to or higher than 300 degrees Celsius.

(2) In the electrode according to the above described aspect, the ratio is in a range of not less than 4.00 and not greater than 8.57. The electrode of this aspect suppresses the occurrence of void and hillock even when the temperature of heating the electrode is in the range of not lower than 350 degrees Celsius and not higher than 450 degrees Celsius.

(3) The electrode according to the above described aspects, further includes a titanium (Ti) layer that is placed between the titanium nitride (TiN) layer and the insulator and is arranged in contact with the titanium nitride (TiN) layer. In the electrode of this aspect, the titanium (Ti) layer is placed between the insulator and the titanium nitride (TiN) layer when the electrode is in contact with the insulator. This structure uses the titanium (Ti) layer to enhance the adhesiveness between the insulator and the titanium nitride (TiN) layer.

(4) In the electrode according to the above described aspects, the thickness of the layer mainly consisting of aluminum (Al) is in a range of not less than 300 nanometers and not greater than 600 nanometers. The electrode of this aspect suppresses the occurrence of void and hillock on the surface of the electrode where the thickness of the layer mainly consisting of aluminum (Al) is in the range of not less than 300 nanometers and not greater than 600 nanometers.

(5) According to another aspect of the invention, there is provided an MIS (metal insulator semiconductor) semiconductor device. The MIS semiconductor device includes the electrode according to any one of claims 1 to 4; the insulator; and a substrate that is in contact with the insulator and contains gallium nitride (GaN). The structure of this aspect improves the operation stability of the MIS semiconductor device by heating the electrode and suppresses the occurrence of void and hillock on the surface of the electrode. Additionally, the configuration of this aspect reduces the production cost of the electrode and thereby reduces the production cost of the MIS semiconductor device.

The invention may be implemented by various other aspects: for example, an MIS semiconductor device including the electrode, a manufacturing apparatus of the MIS semiconductor device, a manufacturing method of the MIS semiconductor device, a wiring electrode and a manufacturing method of the wiring electrode.

The invention suppresses the occurrence of void (concave deformation) and hillock (convex deformation) on the surface of the electrode due to heating. Additionally, the invention has no need to provide a crystalline degradation layer between the titanium nitride (TiN) layer and the layer mainly consisting of aluminum (Al) and thereby reduces the production cost of the electrode. Controlling the ratio of the thickness of the layer mainly consisting of aluminum (Al) to the thickness of the titanium nitride (TiN) layer to be not greater than 12.00 relatively increases the relative thickness of the titanium nitride (TiN) layer relative to the thickness of the layer mainly consisting of aluminum (Al). Titanium nitride has the higher melting point than that of aluminum. Relatively increasing the relative thickness of the titanium nitride (TiN) layer enables the titanium nitride (TiN) layer to be used for suppressing contraction of the layer mainly consisting of aluminum (Al) due to heating. This suppresses the occurrence of hillock on the surface of the electrode. Controlling the ratio of the thickness of the layer mainly consisting of aluminum (Al) to the thickness of the titanium nitride (TiN) layer to be not less than 3.00 suppresses the relative thickness of the titanium nitride (TiN) layer from being excessively increased relative to the thickness of the layer mainly consisting of aluminum (Al). This suppresses the occurrence of void caused by excessive suppression of the contraction of the layer mainly consisting of aluminum (Al) due to heating. The invention suppresses the occurrence of void and hillock even when the temperature of heat treatment is equal to or higher than 300 degrees Celsius.

### BRIEF DESCRIPTION OF THE DRAWINGS

FIG. 1 is a cross sectional view schematically illustrating the structure of an electrode 100 according to one embodiment of the invention;

FIG. 2 is a cross sectional view schematically illustrating the structure of a semiconductor device 200, to which the electrode 100 of the embodiment is applied;

FIG. 3 is a flowchart showing a manufacturing procedure of the electrode 100 according to the embodiment;

FIG. 4 is a table showing the observation results of the outer surfaces of the respective samples s1 to s8 in First Example;

FIG. 5 is a table showing the observation results of the outer surfaces of the respective samples s9 to s13 of Second Example;

FIG. 6 is a cross sectional view schematically illustrating the structure of a first electrode according to one modification;

FIG. 7 is a cross sectional view schematically illustrating the structure of a second electrode according to another modification;

FIG. 8 is a cross sectional view schematically illustrating the structure of a third electrode according to another modification;

FIG. 9 is a cross sectional view schematically illustrating a first structure of a semiconductor device according to one modification;

FIG. 10 is a cross sectional view schematically illustrating a second structure of a semiconductor device according to another modification;

FIG. 11 is a cross sectional view schematically illustrating a third structure of a semiconductor device according to another modification; and

FIG. 12 is a cross sectional view schematically illustrating the structure of a circuit board according to one modification.

### DESCRIPTION OF EMBODIMENTS

### A. EMBODIMENT

### A1. Structures of Electrode and Semiconductor Device

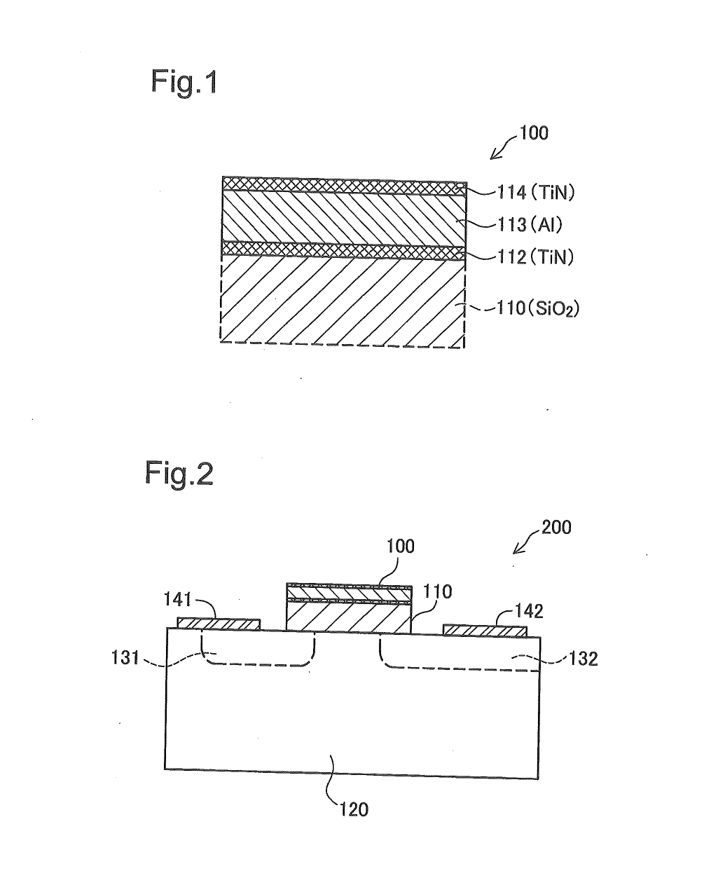

FIG. 1 is a cross sectional view schematically illustrating the structure of an electrode 100 according to one embodiment of the invention. FIG. 2 is a cross sectional view schematically illustrating the structure of a semiconductor device 200, to which the electrode 100 of the embodiment is applied. The semiconductor device 200 shown in FIG. 2 is an MIS semiconductor device having MIS (metal insulator semiconductor) structure, and the electrode 100 shown in FIGS. 1 and 2 is used as a gate electrode of the semiconductor device 200.

As shown in FIG. 1, the electrode 100 has a stacked structure where a first titanium nitride (TiN) layer 112, an aluminum (Al) layer 113 and a second titanium nitride (TiN) layer 114 are stacked in this sequence. The first titanium nitride layer 112 is in contact with an insulating layer 110 described later. In other words, the electrode 100 includes the aluminum layer 113, the first titanium nitride layer 112 that is placed between the aluminum layer 113 and the insulating layer 110 to be in contact with the aluminum layer 113, and the second titanium nitride layer 114 that is placed on the opposite side to the first titanium nitride layer 112 across the aluminum layer 113 to be in contact with the aluminum layer 113.

According to this embodiment, the aluminum layer 113 is made of aluminum (Al). The aluminum layer 113 may be made of an aluminum-containing alloy, such as Al—Si (aluminum silicon alloy) or Al—Cu (aluminum copper alloy), in place of aluminum. In general, the aluminum layer 113 may be provided as a layer mainly consisting of aluminum.

According to this embodiment, the ratio of the thickness (length of each layer along the stacking direction) of the aluminum layer 113 to the thickness of the first titanium nitride layer 112 (hereinafter referred to as “thickness ratio”) is not less than 3.00 and not greater than 12.00. Preferably the thickness ratio is not less than 4.00 and not greater than 8.57. Setting the thickness ratio to any value in this range suppresses the occurrence of a void (concave deformation caused by spread of aluminum) and hillock (convex deformation caused by aggregation of aluminum) on the surface of the electrode, due to heating during manufacturing of the electrode 100. The production procedure of the electrode 100 is described later.

As shown in FIG. 2, the semiconductor device 200 includes the insulating layer 110, a p-type semiconductor layer 120 as a substrate, a first top electrode 141 and a second top electrode 142, in addition to the electrode 100 described above.

According to this embodiment, the insulating layer 110 is made of silicon oxide (SiO₂). This insulating layer 110 may be provided, for example, by formation of a silicon oxide film on the p-type semiconductor layer 120 by ALD (atomic layer deposition) method and subsequent etching.

According to this embodiment, the p-type semiconductor layer 120 is made of silicon (Si). The insulating layer 110 described above is placed on the upper surface of the p-type semiconductor layer 120, and the first top electrode 141 and the second top electrode 142 are also placed on the upper surface of the p-type semiconductor layer 120 to be arranged across the insulating layer 110. A first n+ semiconductor region 131 and a second n+ semiconductor region 132 are formed in the vicinity of the upper surface of the p-type semiconductor layer 120. The first n+ semiconductor region 131 is in contact with the insulating layer 110 and the first top electrode 141. The second n+ semiconductor region 132 is in contact with the insulating layer 110 and the second top electrode 142. These n+ semiconductor regions 131 and 132 are both formed by ion implantation of a high concentration of impurities to the p-type semiconductor layer 120 and heating-induced activation (annealing).

The first top electrode 141 corresponds to a source electrode of the semiconductor device 200. The second top electrode 142 corresponds to a drain electrode of the semiconductor device 200.

### A2. Manufacturing (Formation) Method of Electrode

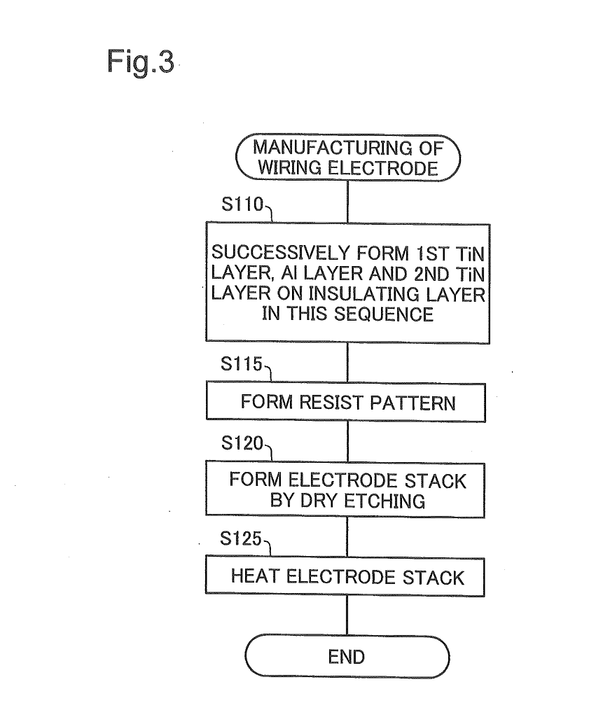

FIG. 3 is a flowchart showing a manufacturing procedure of the electrode 100 according to the embodiment. As shown in FIG. 3, the procedure successively forms the first titanium nitride layer 112, the aluminum layer 113 and the second titanium nitride layer 114 on the insulating layer 110 in this sequence (step S110). The procedure subsequently forms a resist pattern on the second titanium nitride layer 114 (step S115) and forms an electrode stack by dry etching (step S120). The process flow of steps S110 to S120 may be replaced by a process flow of forming a resist pattern, subsequently depositing an electrode material and then performing a lift-off process to form the electrode stack.

The procedure heats the electrode stack (step S125) to complete the electrode 100. At step S125, the process also heats the insulating layer 110 in contact with the electrode stack and the p-type semiconductor layer 120 in contact with the insulating layer 110, in addition to the electrode stack. According to the embodiment, heating at step S125 is performed under the temperature condition of not lower than 300 degrees Celsius. More preferably, heating is performed under the temperature condition of not lower than 350 degrees Celsius. Any arbitrary heating device, such as a lamp, laser, or a furnace tube heat treatment device, may be used for such heating. The “temperature condition” described above means the temperature in a chamber where a heating object is placed, when lamp is used for heating.

The process of step S125 (heat treatment) described above aims to enhance the operation stability of the semiconductor device 200 using the electrode 100.

### B. EXAMPLES

### B1. First Example

Seven different electrodes (samples s2, s3, s4, s5, s6, s7 and s8 described below) were produced according to the above embodiment. One electrode (sample s1 described below) was also produced as Comparative Example. The outer surface (the opposite surface of the second titanium nitride layer 114 opposite to the joint surface in contact with the aluminum layer 113) of each of the samples s1 to s8 after manufacturing was observed with a light microscope to be checked for the occurrence or non-occurrence of void and hillock.

Each of the samples s1 to s8 was manufactured according to the procedure shown in FIG. 3. At step S125 in FIG. 3, each sample was heated at the temperature kept to 400 degrees Celsius in a nitrogen atmosphere for about 30 minutes.

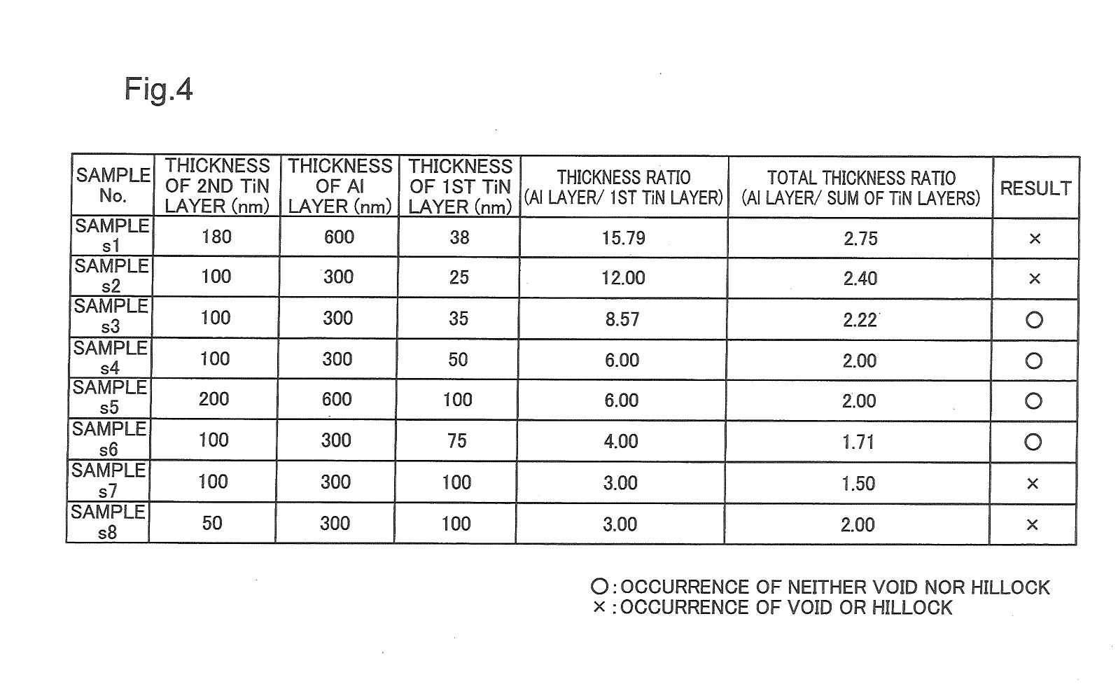

FIG. 4 is a table showing the observation results of the outer surfaces of the respective samples s1 to s8 in First Example. FIG. 4 shows the thickness (nanometers) of the second titanium nitride layer 114, the thickness (nanometers) of the aluminum layer 113, the thickness (nanometers) of the first titanium nitride layer 112, the thickness ratio, and the ratio of the thickness of the aluminum layer 113 to the total thickness of the thickness of the first titanium nitride layer 112 and the thickness of the second titanium nitride layer 114 (hereinafter referred to as “total thickness ratio”), in addition to the observation results (occurrence or non-occurrence of void or hillock) with regard to the respective samples s1 to s8. In these observation results, the symbol “cross mark” indicates the occurrence of void or hillock, and the symbol “open circle” indicates the occurrence of neither void nor hillock.

As shown in FIG. 4, the respective samples s1 to s8 had different combinations of the thickness of the first titanium nitride layer 112, the thickness of the aluminum layer 113 and the thickness of the second titanium nitride layer 114. All the seven samples s2 to s8 had the thickness ratio in the range of not less than 3.00 and not greater than 12.00. The sample s1 of Comparative Example, on the other hand, had the thickness ratio of greater than 12.00. The other features (structure and production method) except the above combination of thicknesses were common to the respective samples s1 to s8.

As shown in FIG. 4, void or hillock (more exactly, void) occurred in the samples s7 and a8 having the thickness ratio of not greater than 3.00. Such occurrence may be attributed to the following reason. The entire aluminum layer 113 is likely to have contraction, i.e., is like to have densification, by heating at step S125 described above. The melting point of the first titanium nitride layer 112 is higher than the melting point of the aluminum layer 113, so that the first titanium nitride layer 112 is unlikely to have contraction (i.e., unlikely to have densification) compared with the aluminum layer 113. When the thickness of the first titanium nitride layer 112 is large relative to the thickness of the aluminum layer 113, i.e., in the case of a relatively low thickness ratio, it is likely that the contraction of the aluminum layer 113 is interfered with by the first titanium nitride layer 112. This causes the occurrence of concave deformation (void) at some locations on the surface of the aluminum layer 113. It is then presumed that similar deformation (void) occurs on the surface of the second titanium nitride layer 114 in contact with the aluminum layer 113.

As shown in FIG. 4, void or hillock (more exactly, hillock) occurred in the samples s1 and s2 having the thickness ratio of not less than 12.00. Such occurrence may be attributed to the following reason. When the thickness of the first titanium nitride layer 112 is small relative to the thickness of the aluminum layer 113, i.e., in the case of a relatively high thickness ratio, like the samples s1 and s2, it is unlikely that the contraction of the aluminum layer 113 is interfered with by the first titanium nitride layer 112. The contraction of the aluminum layer 113 causes the occurrence of convex deformation (hillock) at some locations on the surface of the aluminum layer 113. It is then presumed that similar deformation (hillock) occurs on the surface of the second titanium nitride layer 114 in contact with the aluminum layer 113.

In comparison between the samples s4 and s8, the samples s4 and s8 had the same total thickness ratio “2.00” and the same thickness “300 nanometers” of the aluminum layer 113. There was, however, no occurrence of void or hillock with respect to the sample, while the occurrence of void was observed with respect to the sample s8. Based on these results, it is understood that the thickness involved in the occurrence of void and hillock out of the thickness of the first titanium nitride layer 112 and the thickness of the second titanium nitride layer 114 is the thickness of the first titanium nitride layer 112. The opposite surface of the first titanium nitride layer 112, which is opposite to the joint surface in contact with the aluminum layer 113, is in contact with the insulating layer 110, so that the first titanium nitride layer 112 has high resistance to the contraction of the aluminum layer 113. On the other hand, the opposite surface of the second titanium nitride layer 114, which is opposite to the joint surface in contact with the aluminum layer 113, is open, so that the second titanium nitride layer 114 has low resistance to the contraction of the aluminum layer 113. It is thus presumed that the thickness of the first titanium nitride layer 112 significantly affects the occurrence of void and hillock.

As understood from the results of Second Example described below, even with respect to the sample s2 and the sample s7 described above, the occurrence of void and hillock may be suppressed under some heating conditions at step S125.

### B2. Second Example

Five different electrodes (samples s9, s10, s11, s12 and s13 described below) were manufactured according to the above embodiment. These five electrodes (samples s9 to s13) had different thickness ratios. More specifically, the sample s9 had the thickness ratio of 3.00; the sample s10 had the thickness ratio of 4.00; the sample s11 had the thickness ratio of 6.00; the sample s12 had the thickness ratio of 8.57; and the sample s13 had the thickness ratio of 12.00.

The thickness of the first titanium nitride layer 112, the thickness of the aluminum layer 113 and the thickness of the second titanium nitride layer 114 in the respective samples s9 to s13 were identical with the thickness of the first titanium nitride layer 112, the thickness of the aluminum layer 113 and the thickness of the second titanium nitride layer 114 in the following samples (samples s7, s6, s4, s3 and s2) of First Example:

sample s9: sample s7 of First Example

sample s10: sample s6 of First Example

sample s11: sample s4 of First Example

sample s12: sample s3 of First Example

sample s13: sample s2 of First Example

Five specimens were produced with respect to each of the samples s9 to s13. The five specimens of each sample were subject to different temperature conditions at step S125, but otherwise the manufacturing procedure and the structure were common to these five specimens. More specifically, with regard to each of the samples s9 to s13, the five specimens were manufactured by respectively heating at 300 degrees Celsius, at 350 degrees Celsius, at 400 degrees Celsius, at 450 degrees Celsius and at 500 degrees Celsius. The outer surfaces of the total twenty-five produced specimens were observed with a light microscope to be checked for the occurrence of void and hillock.

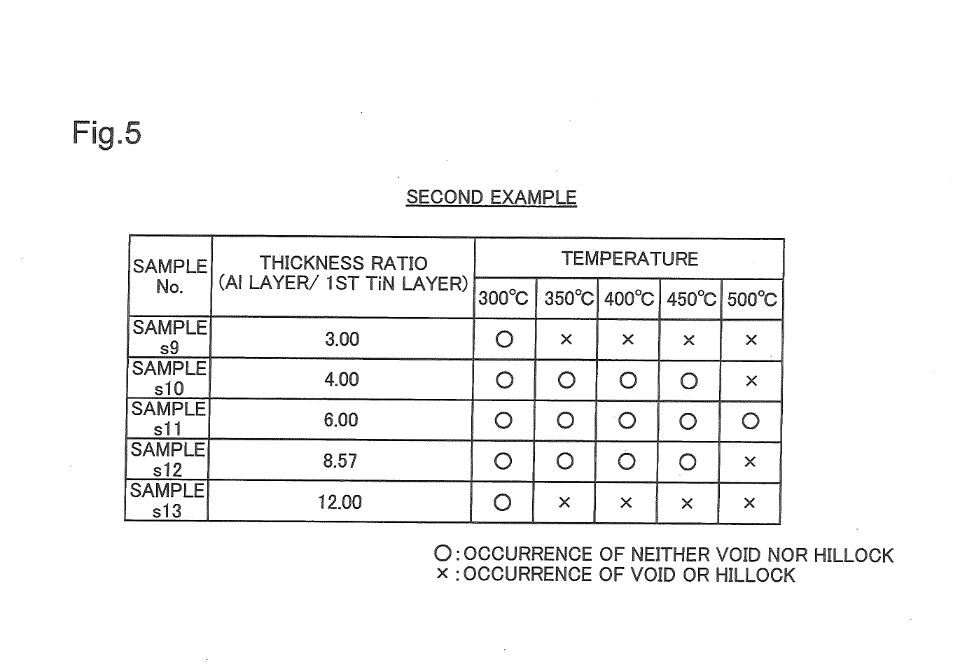

FIG. 5 is a table showing the observation results of the outer surfaces of the respective samples s9 to s13 of Second Example. FIG. 5 shows the thickness ratio in addition to the observation results (occurrence or non-occurrence of void or hillock) with regard to the respective samples s9 to s13.

As shown in FIG. 5, when the heating temperature at step S125 was 300 degrees Celsius, there was no occurrence of void or hillock with respect to any of the samples s9 to s13. This may be attributed to that the contraction of the aluminum layer 113 is suppressed since the heating temperature is relatively low.

When the heating temperature at step S125 is not lower than 350 degrees Celsius and not higher than 450 degrees Celsius, void occurred in the sample s9, and hillock occurred in the sample s13. The reason for the occurrence of void in the sample s9 having the low thickness ratio and the occurrence of hillock in the sample s13 having the relatively high thickness ratio is presumed to be the same reason for the occurrence of void and hillock described in First Example.

When the heating temperature at step S125 is 500 degrees Celsius, void or hillock occurred in all the sample other than the sample s11, i.e., the samples s9, s10, s12 and s13. The reason for the occurrence of void in the samples s9 and s10 having the low thickness ratios and the occurrence of hillock in the samples s12 and s13 having the relatively high thickness ratios is presumed to be the same reason for the occurrence of void and hillock described in First Example.

The higher heating temperature at step S125 has the more significant advantageous effect on improvement of the operation stability of the semiconductor device 200. According to the observation results shown in FIG. 5, the thickness ratio is preferably in the range of not less than 4.00 and not greater than 8.57. This structure suppresses the occurrence of void and hillock on the outer surface of the electrode, while allowing the heating temperature at step S125 to be set in the temperature range of not lower than 350 degrees Celsius and not higher than 450 degrees Celsius.

According to the results of First Example and Second Example described above, controlling the thickness ratio in the range of not less than 3.00 and not greater than 12.00 suppresses the occurrence of void and hillock on the surface (open surface) of the electrode 100. Controlling the thickness ratio in the range of not less than 4.00 and not greater than 8.57 suppresses the occurrence of void and hillock even when the heating temperature at step S125 is not lower than 350 degrees Celsius and not higher than 450 degrees Celsius.

### C. MODIFICATIONS

### C1. Modification 1

In the embodiment and the respective examples described above, the electrode 100 has the stack structure in which the first titanium nitride layer 112, the aluminum layer 113 and the second titanium nitride layer 114 are stacked in the ascending order of the distance from the insulating layer 110. The invention is, however, not limited to this structure.

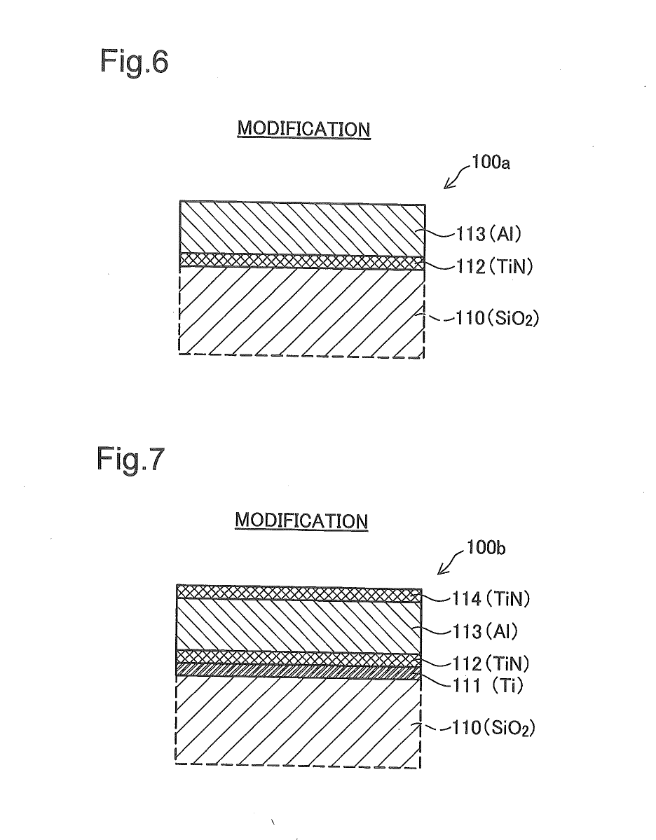

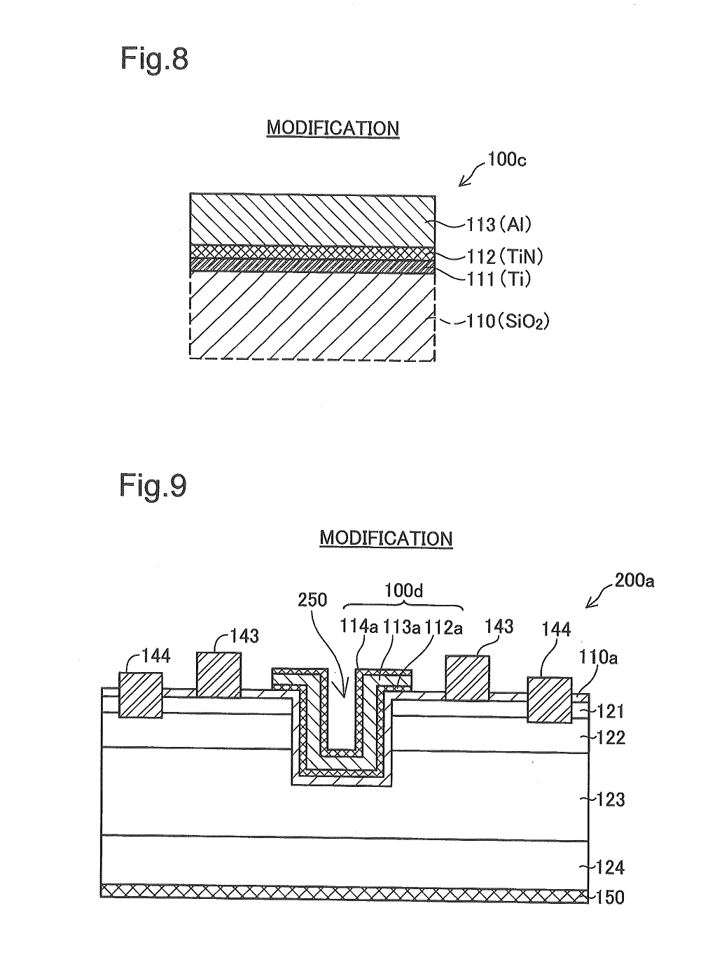

FIG. 6 is a cross sectional view schematically illustrating the structure of a first electrode according to one modification. FIG. 7 is a cross sectional view schematically illustrating the structure of a second electrode according to another modification. FIG. 8 is a cross sectional view schematically illustrating the structure of a third electrode according to another modification.

An electrode 100a shown in FIG. 6 differs from the electrode 100 according to the embodiment and the respective examples described above by omission of the second titanium nitride layer 114, but otherwise has the same structure as that of the electrode 100. More specifically, the electrode 100a has the thickness ratio in the range of not less than 3.00 and not greater than 12.00. The electrode 100a of this structure has the similar advantageous effects to those of the electrode 100 according to the embodiment and the respective examples described above. More specifically, this structure suppresses the occurrence of void and hillock on the outer surface of the aluminum layer 113.

An electrode 100b shown in FIG. 7 differs from the electrode 100 according to the embodiment and the respective examples described above by addition of a titanium (Ti) layer 111, but otherwise has the same structure as that of the electrode 100. More specifically, the electrode 100b has the thickness ratio (ratio of thickness of the aluminum layer 113 to the thickness of the first titanium nitride layer 112) is in the range of not less than 3.00 and not greater than 12.00.

The titanium layer 111 is placed between the first titanium nitride layer 112 and the insulating layer 110 and is arranged in contact with the first titanium layer 112, so as to enhance the adhesiveness between the first titanium nitride layer 112 and the insulating layer 110. The thickness of the titanium layer 111 is about several nanometers to ten-odd nanometers and is significantly smaller than the thickness of the first titanium nitride layer 112. Accordingly, addition of the titanium layer 111 has little influence on the effect of preventing contraction of the aluminum layer 113.

An electrode 100c shown in FIG. 8 differs from the electrode 100 according to the embodiment and the respective examples described above by omission of the second titanium nitride layer 114 and addition of a titanium (Ti) layer 111 which is placed between the first titanium nitride layer 112 and the insulating layer 110 and is arranged in contact with the first titanium layer 112, but otherwise has the same structure as that of the electrode 100. More specifically, the electrode 100c has the thickness ratio in the range of not less than 3.00 and not greater than 12.00. The electrode 100c of this structure has the similar advantageous effects to those of the electrode 100 according to the embodiment and the respective examples described above. More specifically, this structure suppresses the occurrence of void and hillock on the outer surface of the aluminum layer 113. The reason for providing the titanium layer 111 is identical with the reason described above with regard to the electrode 100b and is thus not specifically described here.

### C2. Modification 2

In the embodiment and the respective examples described above, the semiconductor device 200 using the electrode 100 is a planar semiconductor device. The electrode of the invention is, however, not limited to the planar semiconductor device but is also applicable to a trench semiconductor device.

FIG. 9 is a cross sectional view schematically illustrating a first structure of a semiconductor device according to one modification. As shown in FIG. 9, a semiconductor device 200a is a trench semiconductor device (MIS semiconductor device). The semiconductor device 200a includes a trench 250, an electrode 100d, a source electrode 143, a p-body electrode 144, a drain electrode (back electrode) 150, an insulating layer 110a, an n+-type semiconductor layer (n+GaN) 121, a p-type semiconductor layer (pGaN) 122, an n-type semiconductor layer (nGaN) 123 and a substrate 124.

The trench 250 is extended from the outer surface (open surface) of the electrode 100d through the n+-type semiconductor layer 121 and the p-type semiconductor layer 122 to reach the n-type semiconductor layer 123.

The electrode 100d has a bottomed tubular external shape. The electrode 100d serves as a gate electrode of the semiconductor device 200a and includes a first titanium nitride layer 112a, an aluminum layer 113a and a second titanium nitride layer 114a. The first titanium nitride layer 112a corresponds to the first titanium layer 112 described above. Similarly the aluminum layer 113a corresponds to the aluminum layer 113 described above, and the second titanium layer 114a corresponds to the second titanium layer 114 described above. The electrode 100d accordingly has the thickness ratio in the range of not less than 3.00 and not greater than 12.00.

The first titanium nitride layer 112a is formed on the insulating layer 110a. The aluminum layer 113a is formed on the first titanium nitride layer 112a. The second titanium nitride layer 114a is formed on the aluminum layer 113a.

The source electrode 143 has a tubular external shape and is arranged to surround the electrode 100d. The source electrode 143 is arranged in contact with the n+-type semiconductor layer 121 in the thickness direction (Z-axis direction). The p-body electrode 144 has a tubular external shape and is arranged to surround the source electrode 143. The p-body electrode 144 is arranged in contact with the p-type semiconductor layer 122 in the thickness direction (Z-axis direction). The drain electrode 150 is arranged in contact with the rear surface of the substrate 124 (opposite surface that is opposite to the joint face in contact with the n-type semiconductor layer 123). The insulating layer 110a corresponds to the insulating layer 110 described above and is provided as a silicon oxide (SiO₂) layer formed on the n+-type semiconductor layer 121.

The n-type semiconductor layer 123 is formed on the substrate 124. The p-type semiconductor layer 122 is formed on the n-type semiconductor layer 123. The n+-type semiconductor layer 121 is formed on the p-type semiconductor layer 122.

The semiconductor device 200a of the above structure includes the electrode 100d, which has the similar structure to those of the electrodes 100 and 100a to 100c according to the embodiment and the respective examples and the respective modifications described above, and accordingly has the similar advantageous effects to those of the semiconductor device 200. More specifically, this structure suppresses the occurrence of void and hillock by heating at step S125 and reduces the manufacturing cost of the electrode 100d.

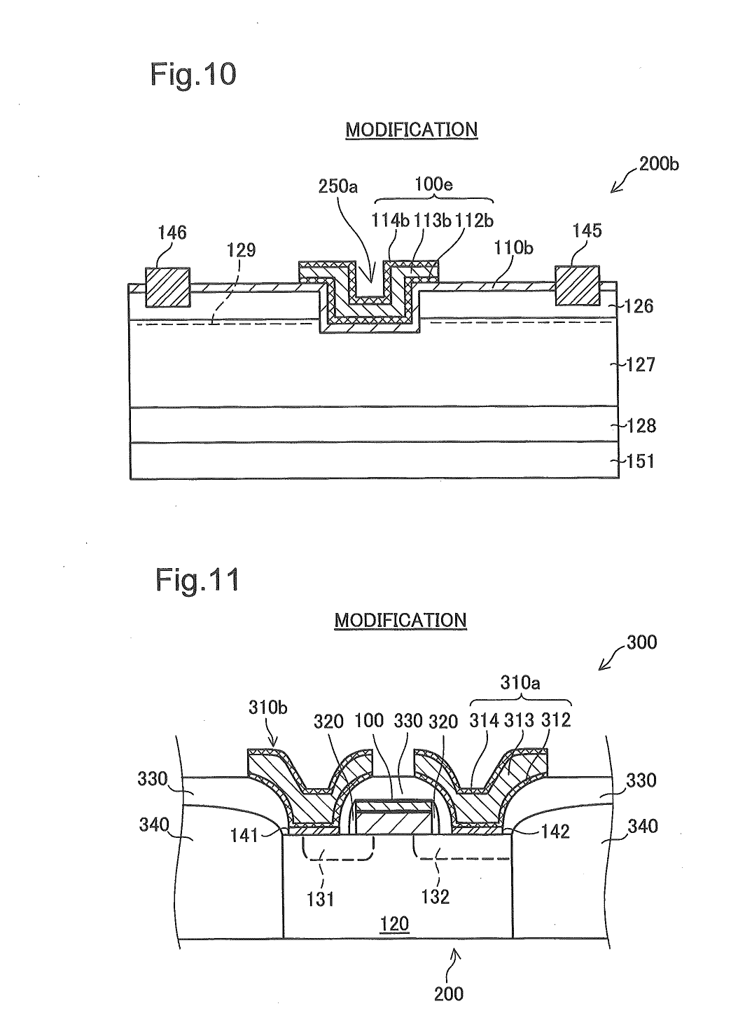

FIG. 10 is a cross sectional view schematically illustrating a second structure of a semiconductor device according to another modification. A semiconductor device 200b shown in FIG. 10 is a trench semiconductor device (MIS semiconductor device) like the semiconductor device 200a shown in FIG. 9. The semiconductor device 200b includes a trench 250a, an electrode 100e, a drain electrode 145, a source electrode 146, an insulating layer 110b, a barrier layer (AlGaN) 126, an n-type semiconductor layer (nGaN) 127, a buffer layer 128 and a substrate 151. The trench 250a is extended from the outer surface of the electrode 100e through the barrier layer 126 to reach the n-type semiconductor layer 127.

The electrode 100e serves as a gate electrode of the semiconductor device 200b and includes a first titanium nitride layer 112b, an aluminum layer 113b and a second titanium nitride layer 114b. The first titanium nitride layer 112b corresponds to the first titanium layer 112 described above. Similarly the aluminum layer 113b corresponds to the aluminum layer 113 described above, and the second titanium layer 114b corresponds to the second titanium layer 114 described above. The electrode 100e accordingly has the thickness ratio in the range of not less than 3.00 and not greater than 12.00.

The first titanium nitride layer 112b is formed on the insulating layer 110b. The aluminum layer 113b is formed on the first titanium nitride layer 112b. The second titanium nitride layer 114b is formed on the aluminum layer 113b.

The drain electrode 145 and the source electrode 146 are both arranged in contact with the barrier layer 126. The insulating layer 110b corresponds to the insulating layer 110 described above and is provided as a silicon oxide (SiO₂) layer formed on the barrier layer 126.

The buffer layer 128 is formed on the substrate 151. The n-type semiconductor layer 127 is formed on the buffer layer 128. The barrier layer 126 is formed on the n-type semiconductor layer 127. The n-type semiconductor layer 127 contains a two-dimensional electron gas 129 in the neighborhood of the boundary with the barrier layer 126.

The semiconductor device 200b of the above structure includes the electrode 100e, which has the similar structure to those of the electrodes 100 and 100a to 100c according to the embodiment and the respective examples and the respective modifications described above, and accordingly has the similar advantageous effects to those of the semiconductor device 200. More specifically, this structure suppresses the occurrence of void and hillock by heating at step S125 and reduces the manufacturing cost of the electrode 100e.

### C3. Modification 3

In the embodiment, the respective examples and the respective modifications described above, each of the electrodes 100 and 100a to 100d is employed as the gate electrode of the semiconductor device 200 or 200a. The invention is, however, not limited to the gate electrode. For example, the invention is applicable to any device electrode, for example, a wiring electrode that covers the surface of a semiconductor device or a wiring electrode that is used for a circuit board.

FIG. 11 is a cross sectional view schematically illustrating a third structure of a semiconductor device according to another modification. In Modification 3, the electrode of the invention is employed as the gate electrode of the semiconductor device 200 described above and is also employed as a wiring electrode provided on the surface of the semiconductor device 200.

As shown in FIG. 11, a semiconductor device 300 of Modification 3 corresponds to a product of FEOL (front end of line) producing an element such as a transistor. The semiconductor device 300 includes a semiconductor device 200, an isolation part 340, a spacer 320, a planarized insulating film 330 and two wiring electrodes 310a and 310b. Another semiconductor device (transistor) is arranged on the other side of the semiconductor device 200 across the isolation part 340, although not specifically illustrated.

The semiconductor device 200 is identical with the semiconductor device 200 according to the embodiment and the respective examples described above, and is thus not specifically described here. The isolation part 340 electrically insulates and isolates adjacent semiconductor devices (transistors) from each other. The isolation part 340 may be made of, for example, silicon oxide (SiO₂). The planarized insulating film 330 corresponds to BPSG (boron phosphorus silicon glass) and serves for interlayer insulation and isolation. The planarized insulating film 330 is arranged to cover the electrode 100 and to surround the two wiring electrodes 310a and 310b. The spacer 320 is placed between the electrode 100 and the planarized insulating film 330 to fill the gap between the electrode 100 and the planarized insulating film 330.

The wiring electrode 310a is used to be connected with a second top electrode 142 in BEOL (back end of line) forming a wiring structure for wiring for interconnection of elements or grounding. The wiring electrode 310a includes a first titanium nitride layer 312, an aluminum layer 313 and a second titanium nitride layer 314. The first titanium nitride layer 312 corresponds to the first titanium nitride layer 112 described above. Similarly the aluminum layer 313 corresponds to the aluminum layer 113 described above, and the second titanium layer 314 corresponds to the second titanium layer 114 described above. The electrode 310a accordingly has the thickness ratio in the range of not less than 3.00 and not greater than 12.00.

The first titanium nitride layer 312 is formed on the second top electrode 142 and the planarized insulating film 330. The aluminum layer 313 is formed on the first titanium nitride layer 312. The second titanium nitride layer 314 is formed on the aluminum layer 313. The structure of the wiring electrode 310b is similar to the structure of the wiring electrode 310a described above and is thus not specifically described here.

The semiconductor device 300 of the above structure suppresses the occurrence of void and hillock on the surface of the electrode 100 and the wiring electrodes 310a and 310b, while reducing the manufacturing cost of the electrode 100 and the wiring electrodes 310a and 310b.

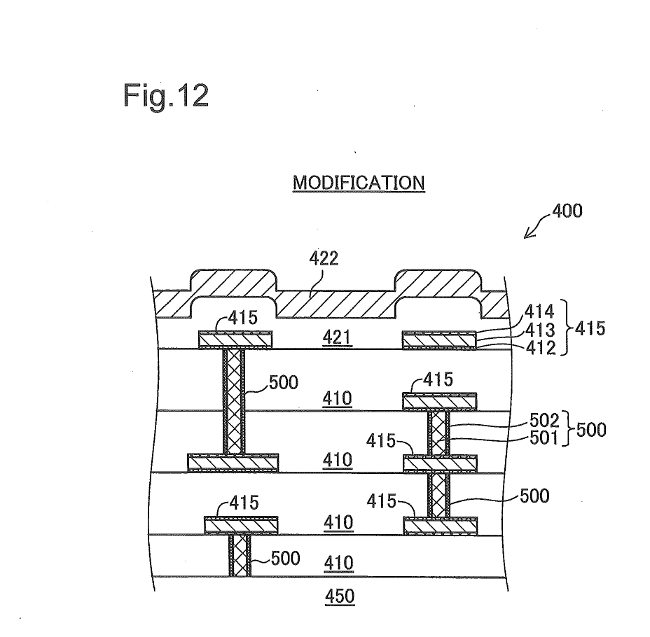

FIG. 12 is a cross sectional view schematically illustrating the structure of a circuit board according to one modification. As shown in FIG. 12, a circuit board 400 of Modification 3 corresponds to a product of BEOL. The circuit board 400 includes a plurality of insulating layers 410 stacked on a substrate 450 obtained as a product of FEOL, wiring electrodes 415 provided between the adjacent insulating layers, vias 500 arranged to interconnect the wiring electrodes 415 along the stacking direction of the respective layers, a first passivation film 421 and a second passivation film 422.

For example, the semiconductor device 300 shown in FIG. 11 may be employed as the substrate 450. The respective insulating layers 410 may be made of, for example, silicon oxide (SiO₂). The wiring electrode 415 includes a first titanium nitride layer 412, an aluminum layer 413 and a second titanium nitride layer 414. The first titanium nitride layer 412 corresponds to the first titanium nitride layer 112 described above. Similarly the aluminum layer 413 corresponds to the aluminum layer 113 described above, and the second titanium layer 414 corresponds to the second titanium layer 114 described above. The electrode 415 accordingly has the thickness ratio in the range of not less than 3.00 and not greater than 12.00.

The via 500 has electrical conductivity and is used to electrically interconnect the wiring electrodes 415. The via 500 is arranged in a through hole formed in the insulating layer 410 in the thickness direction. The via 500 includes a center section 501 and an outer peripheral section 502 arranged around the periphery of the center section 501. The center section 501 may be made of, for example, tungsten (W). The outer peripheral section 502 may be made of, for example, titanium nitride (TiN).

Both the first passivation film 421 and the second passivation film 422 serve to protect the surface of the circuit board 400. The first passivation film 421 may be made of, for example, silicon oxide (SiO₂). The second passivation film 422 may be made of, for example, silicon nitride (SiN).

The circuit board 400 of the above structure suppresses the occurrence of void and hillock on the surface of the wiring electrodes 415 and reduces the manufacturing cost of the wiring electrodes 415.

### C4. Modification 4

In the embodiment, the respective examples and the respective modifications described above, the insulating layers 110, 110a and 410 are made of silicon oxide (SiO2). These insulating layers 110, 110a and 410 may alternatively be made of zirconium oxynitride (ZrON), instead of silicon oxide. In the embodiment, the respective examples and the respective modifications described above, the p-type semiconductor layer 120 is made of gallium nitride (GaN). The p-type semiconductor layer 120 may alternatively be made of silicon (Si), instead of gallium nitride.

### C5. Modification 5

In Modification 3 described above, the semiconductor device 300 includes the semiconductor device 200 having the electrode of the invention. The semiconductor device 200 may, however, be replaced with another semiconductor device having an electrode different from the electrode of the invention. In this modification, for example, a MOS semiconductor device (MOSFET: metal-oxide-semiconductor field-effect transistor) may be employed in place of the semiconductor device 200. In this modification, application of the electrode of the invention to the wiring electrodes 310a and 310b suppresses the occurrence of void and hillock on the surfaces of the wiring electrodes 310a and 310b.

The invention is not limited to the above embodiments, examples or modifications, but a diversity of variations and modifications may be made to the embodiments without departing from the scope of the invention. For example, the technical features of the embodiments, examples or modifications corresponding to the technical features of the respective aspects described in SUMMARY OF INVENTION may be replaced or combined appropriately, in order to solve part or all of the problems described above or in order to achieve part or all of the advantageous effects described above. Any of the technical features may be omitted appropriately unless the technical feature is described as essential herein.

What is claimed is:

1. An electrode used in contact with an insulator, the electrode comprising:
a layer mainly consisting of aluminum (Al); and
a titanium nitride (TiN) layer that is placed between the layer mainly consisting of aluminum (Al) and the insulator and is arranged in contact with the layer mainly consisting of aluminum (Al),
wherein a ratio of thickness of the layer mainly consisting of aluminum (Al) to thickness of the titanium nitride (TiN) layer is in a range of not less than 3.00 and not greater than 12.00.

2. The electrode according to claim 1,
wherein the ratio is in a range of not less than 4.00 and not greater than 8.57.

3. The electrode according to claim 1, further comprising:
a titanium (Ti) layer that is placed between the titanium nitride (TiN) layer and the insulator and is arranged in contact with the titanium nitride (TiN) layer.

4. The electrode according to claim 1,
wherein the thickness of the layer mainly consisting of aluminum (Al) is in a range of not less than 300 nanometers and not greater than 600 nanometers.

5. An MIS (metal insulator semiconductor) semiconductor device, comprising:
the electrode according to claim 1;
the insulator; and
a substrate that is in contact with the insulator and contains gallium nitride (GaN).

6. A manufacturing method of an electrode used in contact with an insulator, comprising:
forming a titanium nitride (TiN) layer on the insulator either via a titanium (Ti) layer or not via the titanium (Ti) layer but directly;
forming a layer mainly consisting of aluminum (Al) on the titanium nitride (TiN) layer, wherein a ratio of thickness of the layer mainly consisting of aluminum (Al) to thickness of the titanium nitride (TiN) layer is in a range of not less than 3.00 and not greater than 12.00; and
after forming the layer mainly consisting of aluminum (Al), heating at a temperature of not lower than 300 degrees Celsius.

7. The manufacturing method according to claim 6,
wherein the ratio is in a range of not less than 4.00 and not greater than 8.57 in the forming a layer mainly consisting of aluminum (Al) on the titanium nitride (TiN) layer, and
heating at a temperature of not lower than 350 degrees Celsius and not higher than 450 degrees Celsius in the heating.
